(19) United States
(12) Patent Application Publication
(10) Pub. No.: US 2024/0254625 A1
(43) Pub. Date: Aug. 1, 2024

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Kimihiko NAKATANI, Toyama-shi (JP); Ryuji YAMAMOTO, Tokyo (JP)

(73) Assignee: Kokusai Electric Corporation, Tokyo (JP)

(21) Appl. No.: 18/598,293

(22) Filed: Mar. 7, 2024

Related U.S. Application Data
(63) Continuation of application No. PCT/JP22/33085, filed on Sep. 2, 2022.

(30) Foreign Application Priority Data
Sep. 27, 2021 (JP) 2021-157161

(51) Int. Cl. C23C 16/455; C23C 16/52; H01L 21/02

(52) U.S. Cl. CPC C23C 16/45534; C23C 16/52; H01L 21/02123; H01L 21/0228

(57) ABSTRACT

There is provided a technique including forming an inhibitor layer on a first surface of a substrate having the first surface and a second surface by supplying a modifying agent to the substrate to adsorb inhibitor molecules contained in the modifying agent on the first surface, and forming a film on the second surface by supplying a film-forming agent containing a catalyst to the substrate after forming the inhibitor layer on the first surface. A width of each of the inhibitor molecules is a, an interval between adsorption sites on the first surface is b, and a width of a catalyst molecule constituting the catalyst is c, where c>b−a is satisfied when a is smaller than b, and c>xb−a (x is the smallest integer that satisfies a<xb) is satisfied when a is larger than b.

### REFERENCE TO RELATED APPLICATIONS

This application is a Bypass Continuation application of International Application No. PCT/JP2022/033085 having an international filing date of Sep. 2, 2022 and designating the United States, the International Application being based upon and claiming the benefit of priority from Japanese Patent Application No. 2021-157161, filed on Sep. 27, 2021, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND OF THE INVENTION

In the related art, as a process of manufacturing a semiconductor device, a process of selectively growing and forming a film on a specific surface among a plurality of types of surfaces made of different materials which are exposed on a surface of a substrate (hereinafter, this process is also referred to as selective growth or selective film formation) may be often performed.

However, depending on a modifying agent or a film-forming agent used when performing the selective growth, it may be difficult to selectively grow the film on the specific surface among the plurality of types of surfaces.

### SUMMARY OF THE INVENTION

Some embodiments of the present disclosure provide a technique capable of selectively forming a film on a desired surface with high precision.

According to one aspect of the present disclosure, there is provided a technique including: forming an inhibitor layer on a first surface of a substrate having the first surface and a second surface by supplying a modifying agent to the substrate to adsorb inhibitor molecules contained in the modifying agent on the first surface; and forming a film on the second surface by supplying a film-forming agent containing a catalyst to the substrate after forming the inhibitor layer on the first surface, wherein a width of each of the inhibitor molecules is a, an interval between adsorption sites on the first surface is b, and a width of a catalyst molecule constituting the catalyst is c, where c>b−a is satisfied when a is smaller than b, and c>xb−a (x is the smallest integer that satisfies a<xb) is satisfied when a is larger than b.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in an embodiment of the present disclosure, in which a portion of the process furnace is shown in a vertical cross section.

FIG. 2 is a schematic configuration view of the vertical process furnace of the substrate processing apparatus suitably used in the embodiment of the present disclosure, in which a portion of the process furnace is shown in a cross section taken along line A-A in FIG. 1.

FIG. 3 is a schematic configuration diagram of a controller of the substrate processing apparatus suitably used in the embodiment of the present disclosure, in which a control system of the controller is shown in a block diagram.

FIG. 4 is a diagram showing a processing sequence in an embodiment of the present disclosure.

FIG. 5A is a schematic cross-sectional view showing a surface portion of a wafer having a first surface and a second surface, with a natural oxide film formed on the second surface.

FIG. 5B is a schematic cross-sectional view showing the surface portion of the wafer after the natural oxide film is removed from the second surface by performing a cleaning step from a state of FIG. 5A.

FIG. 5C is a schematic cross-sectional view showing the surface portion of the wafer after an inhibitor layer is formed on the first surface by performing a modifying step from a state of FIG. 5B.

FIG. 5D is a schematic cross-sectional view showing the surface portion of the wafer after a film is selectively formed on the second surface by performing a film-forming step from a state of FIG. 5C.

FIG. 5E is a schematic cross-sectional view showing the surface portion of the wafer after the inhibitor layer on the first surface is removed by performing a heat-treating step from a state of FIG. 5D.

FIG. 6A is a schematic cross-sectional view showing adsorption sites on the first surface of the wafer before supplying the modifying agent.

FIG. 6B is a schematic cross-sectional view showing a state in which inhibitor molecules are adsorbed on the adsorption sites on the first surface of the wafer.

FIG. 6C is a schematic cross-sectional view showing a state in which the inhibitor molecules act as a steric hindrance to catalyst molecules and block the catalyst molecules from passing through inter-molecular gaps of the inhibitor molecules to reach the first surface of the wafer.

FIG. 7 is a schematic cross-sectional view illustrating a state in which c>b−a is satisfied when a width of an inhibitor molecule is a, an interval between the adsorption sites on the first surface of the wafer is b, and a width of a catalyst molecule is c, where a is smaller than b.

FIG. 8 is a schematic cross-sectional view illustrating a state in which c>xb−a (x is the smallest integer satisfying a<xb) is satisfied when the width of the inhibitor molecule is a, the interval between the adsorption sites on the first surface of the wafer is b, and the width of the catalyst molecule is c, where a is larger than b.

FIG. 9 is a schematic cross-sectional view showing a state in which the inhibitor molecules act as a steric hindrance to catalyst molecules and block the catalyst molecules from passing through the inter-molecular gaps of the inhibitor molecules to reach the first surface of the wafer by satisfying c>b−a when the width of the inhibitor molecule is a, the interval between the adsorption sites on the first surface of the wafer is b, and the width of the catalyst molecule is c, where a is smaller than b.

FIG. 10 is a schematic cross-sectional view showing a state in which the inhibitor molecules act as the steric hindrance to the catalyst molecules and block the catalyst molecules from passing through the inter-molecular gaps of the inhibitor molecules to reach the first surface of the wafer by satisfying c>xb−a (x is the smallest integer satisfying a<xb) when the width of the inhibitor molecule is a, the interval between the adsorption sites on the first surface of the wafer is b, and the width of the catalyst molecule is c, where a is larger than b.

FIG. 11 is a diagram showing a processing sequence in Modification 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

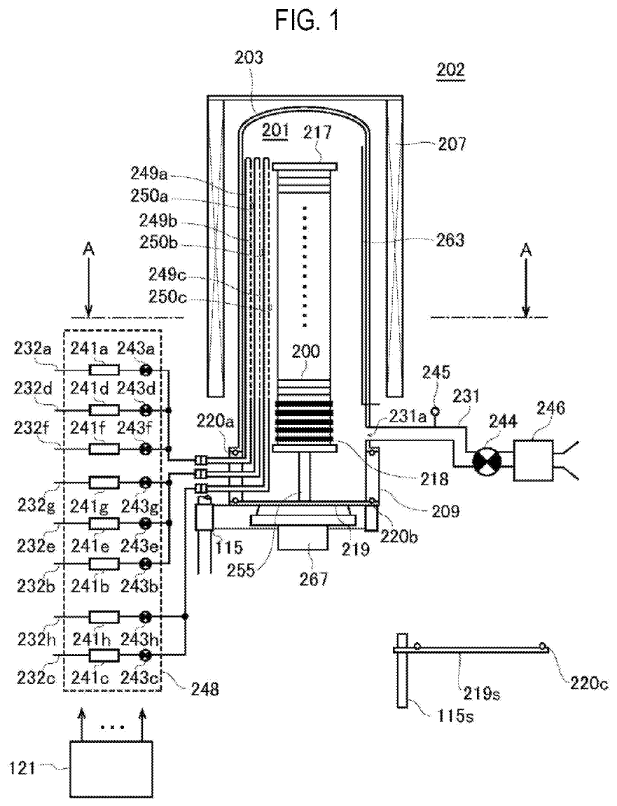

One embodiment of the present disclosure will now be described mainly with reference to FIGS. 1 to 4 and 5A to 5E. In addition, it should be noted that the drawings used in the following description are all schematic, and the relationships between dimensions of respective elements, the ratios of the respective elements, and the like may differ from reality. Also, there may be a case where the relationship of dimensions and the ratios differ from each other between the drawings.

### (1) Configuration of Substrate Processing Apparatus

As shown in FIG. 1, a process furnace 202 includes a heater 207 as a temperature adjustor (a heating part). The heater 207 has a cylindrical shape and is supported by a support plate so as to be vertically installed. The heater 207 also functions as an activation mechanism (an excitation part) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and has a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and has a cylindrical shape with both of its upper and lower ends opened. An upper end portion of the manifold 209 engages with a lower end portion of the reaction tube 203 so as to support the reaction tube 203. An O-ring 220a serving as a seal member is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed inside the process chamber 201.

Nozzles 249a to 249c as first to third suppliers are provided inside the process chamber 201 so as to penetrate through a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles. Each of the nozzles 249a and 249c is provided adjacent to the nozzle 249b.

Mass flow controllers (MFCs) 241a to 241c, which are flow rate controllers (flow rate control parts), and valves 243a to 243c, which are opening/closing valves, are provided in the gas supply pipes 232a to 232c, respectively, sequentially from the upstream side of a gas flow. Each of gas supply pipes 232d and 232f is respectively connected to the gas supply pipe 232a at the downstream side of the valves 243a. Each of gas supply pipes 232e and 232g is connected to the gas supply pipe 232b at the downstream side of the valves 243b. A gas supply pipe 232h is connected to the gas supply pipe 232c at the downstream side of the valves 243c. MFCs 241d to 241h and valves 243d to 243h are provided in the gas supply pipes 232d to 232h, respectively, sequentially from the upstream side of a gas flow. The gas supply pipes 232a to 232h are made of, for example, a metal material such as SUS.

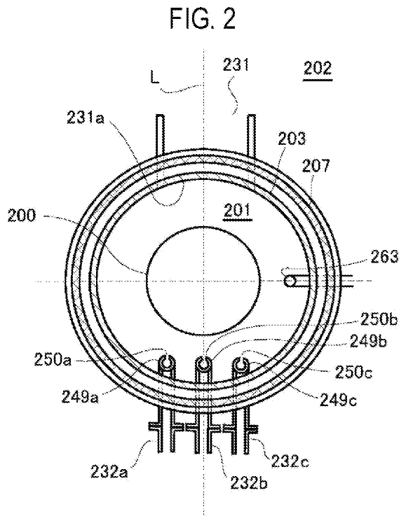

As shown in FIG. 2, each of the nozzles 249a to 249c is provided in an annular space (in a plan view) between an inner wall of the reaction tube 203 and the wafers 200 so as to extend upward from a lower portion of the inner wall of the reaction tube 203 to an upper portion thereof along an arrangement direction of the wafers 200. That is, each of the nozzles 249a to 249c is provided in a region horizontally surrounding a wafer arrangement region in which the wafers 200 are arranged at a lateral side of the wafer arrangement region, along the wafer arrangement region. In a plan view, the nozzle 249b is disposed so as to face an exhaust port 231a (to be described later) on a straight line with the centers of the wafers 200 loaded into the process chamber 201, which are interposed therebetween. The nozzles 249a and 249c are arranged so as to sandwich a straight line L passing through the nozzle 249b and the center of the exhaust port 231a from both sides along the inner wall of the reaction tube 203 (outer peripheral portions of the wafers 200). The straight line L is also a straight line passing through the nozzle 249b and the centers of the wafers 200. That is, it may be said that the nozzle 249c is provided on the side opposite to the nozzle 249a with the straight line L interposed therebetween. The nozzles 249a and 249c are arranged in a line symmetrical relationship with the straight line L as an axis of symmetry. Gas supply holes 250a to 250c for supplying a gas are formed on side surfaces of the nozzles 249a to 249c, respectively. Each of the gas supply holes 250a to 250c is opened so as to oppose (face) the exhaust port 231a in a plan view, which enables a gas to be supplied toward the wafers 200. A plurality of gas supply holes 250a to 250c are formed from the lower portion of the reaction tube 203 to the upper portion thereof.

A modifying agent is supplied from the gas supply pipe 232a into the process chamber 201 via the MFC 241a, the valve 243a, and the nozzle 249a.

A raw material is supplied from the gas supply pipe 232b into the process chamber 201 via the MFC 241b, the valve 243b, and the nozzle 249b. The raw material is used as one of film-forming agents.

A reactant is supplied from the gas supply pipe 232c into the process chamber 201 via the MFC 241c, the valve 243c, and the nozzle 249c. The reactant is used as one of the film-forming agents.

A catalyst is supplied from the gas supply pipe 232d into the process chamber 201 via the MFC 241d, the valve 243d, the gas supply pipe 232a, and the nozzle 249a. The catalyst is used as one of the film-forming agents.

A cleaning agent or a regulating agent is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like.

A modifying agent supply system mainly includes the gas supply pipe 232a, the MFC 241a, and the valve 243a. A raw material supply system mainly includes the gas supply pipe 232b, the MFC 241b, and the valve 243b. A reactant supply system mainly includes the gas supply pipe 232c, the MFC 241c, and the valve 243c. A catalyst supply system mainly includes the gas supply pipe 232d, the MFC 241d, and the valve 243d. A cleaning agent supply system or a regulating agent supply system mainly includes the gas supply pipe 232e, the MFC 241e, and the valve 243e. An inert gas supply system mainly includes the gas supply pipes 232f to 232h, the MFCs 241f to 241h, and the valves 243f to 243h. Each or all of the raw material supply system, the reactant supply system, and the catalyst supply system are also referred to as a film-forming agent supply system.

One or all of the above-described various supply systems may be configured as an integrated-type supply system 248 in which the valves 243a to 243h, the MFCs 241a to 241h, and the like are integrated. The integrated-type supply system 248 is connected to each of the gas supply pipes 232a to 232h. In addition, the integrated-type supply system 248 is configured such that operations of supplying various materials (various gases) into the gas supply pipes 232a to 232h (that is, the opening/closing operation of the valves 243a to 243h, the flow rate adjustment operation by the MFCs 241a to 241h, and the like) are controlled by a controller 121 which will be described later. The integrated-type supply system 248 may be configured as an integral type or detachable-type integrated unit, and may be attached to and detached from the gas supply pipes 232a to 232h and the like on an integrated unit basis, so that the maintenance, replacement, extension and the like of the integrated-type supply system 248 may be performed on an integrated unit basis.

The exhaust port 231a for exhausting an internal atmosphere of the process chamber 201 is provided below the sidewall of the reaction tube 203. As shown in FIG. 2, in a plan view, the exhaust port 231a is provided at a position opposing (facing) the nozzles 249a to 249c (the gas supply holes 250a to 250c) with the wafers 200 interposed therebetween. The exhaust port 231a may be provided from a lower portion of the sidewall of the reaction tube 203 to an upper portion thereof, that is, along the wafer arrangement region. An exhaust pipe 231 is connected to the exhaust port 231a. A vacuum pump 246 as a vacuum exhaust device is connected to the exhaust pipe 231 via a pressure sensor 245, which is a pressure detector (pressure detection part) for detecting the internal pressure of the process chamber 201, and an auto pressure controller (APC) valve 244, which is a pressure regulator (pressure adjustment part). The APC valve 244 is configured to perform or stop a vacuum exhaust operation for the interior of the process chamber 201 by opening/closing the valve while the vacuum pump 246 is actuated. Further, the APC valve 244 is configured to adjust the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening cover configured to hermetically seal a lower end opening of the manifold 209, is provided under the manifold 209. The seal cap 219 is made of, for example, a metal material such as SUS, and is formed in a disc shape. An O-ring 220b, which is a seal member making contact with the lower end of the manifold 209, is provided on an upper surface of the seal cap 219. A rotation mechanism 267 configured to rotate a boat 217 (to be described later) is installed under the seal cap 219. A rotary shaft 255 of the rotation mechanism 267 is connected to the boat 217 through the seal cap 219. The rotation mechanism 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down.

A shutter 219s, which serves as a furnace opening cover configured to hermetically seal a lower end opening of the manifold 209 in a state where the seal cap 219 is lowered and the boat 217 is unloaded from the process chamber 201, is provided under the manifold 209. The shutter 219s is made of, for example, a metal material such as SUS, and is formed in a disc shape. An O-ring 220c, which is a seal member making contact with the lower end of the manifold 209, is provided on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of (for example, 25 to 200) wafers in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC, are installed below the boat 217 in multiple stages.

A temperature sensor 263 serving as a temperature detector is installed inside the reaction tube 203. Based on temperature information detected by the temperature sensor 263, a state of supplying electric power to the heater 207 is adjusted such that an interior of the process chamber 201 has a desired temperature distribution. The temperature sensor 263 is provided along the inner wall of the reaction tube 203.

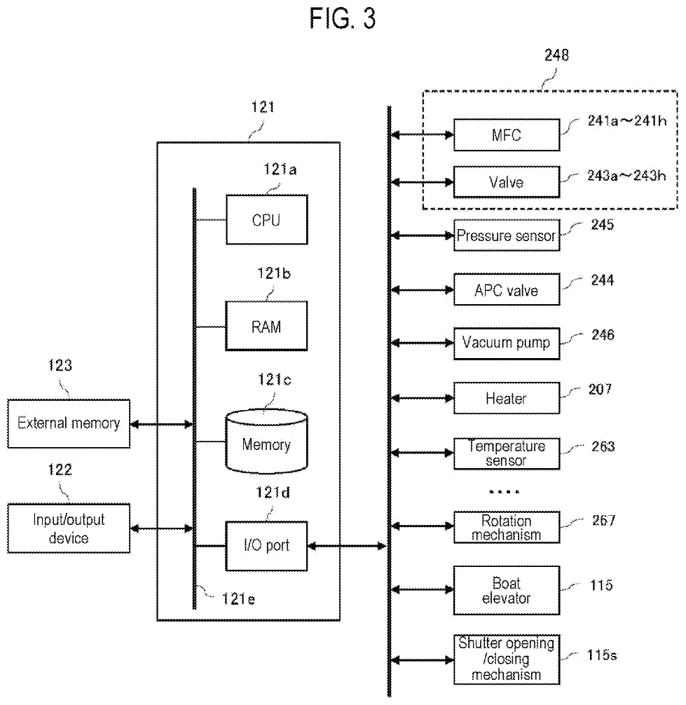

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted with, e.g., a touch panel or the like, is connected to the controller 121. Further, an external memory 123 may be connected to the controller 121.

The memory 121c is configured by, for example, a flash memory, a hard disk drive (HDD), a solid state drive (SSD), or the like. A control program for controlling operations of a substrate processing apparatus, a process recipe in which sequences and conditions of substrate processing to be described later are written, or the like, are readably recorded and stored in the memory 121c. The process recipe functions as a program that causes, by the controller 121, the substrate processing apparatus to execute each sequence in the substrate processing (to be described later) to obtain an expected result. Hereinafter, the process recipe and the control program may be generally and simply referred to as a “program”. Further, the process recipe may be simply referred to as a “recipe”. When the term “program” is used herein, it may indicate a case of including the recipe alone, a case of including the control program alone, or a case of including both the recipe and the control program. The RAM 121b is configured as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotation mechanism 267, the boat elevator 115, the shutter opening/closing mechanism 115s, and the like.

The CPU 121a is configured to read and execute the control program from the memory 121c. The CPU 121a is also configured to read the recipe from the memory 121c according to an operation command input by the input/output device 122. The CPU 121a is configured to control the flow rate adjusting operation of various kinds of materials (gases) by the MFCs 241a to 241h, the opening/closing operation of the valves 243a to 243h, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down by the boat elevator 115, the opening/closing operation of the shutter 219s by the shutter opening/closing mechanism 115s, and the like, according to contents of the read recipe.

The controller 121 may be configured by installing, on the computer, the afore-mentioned program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is configured as a non-transitory computer-readable recording medium. Hereinafter, the memory 121c and the external memory 123 may be generally and simply referred to as a “recording medium”. When the term “recording medium” is used herein, it may indicate a case of including the memory 121c alone, a case of including the external memory 123 alone, or a case of including both the memory 121c and the external memory 123. Further, the program may be provided to the computer using communication means such as the Internet or a dedicated line, instead of using the external memory 123.

### (2) Substrate Processing Process

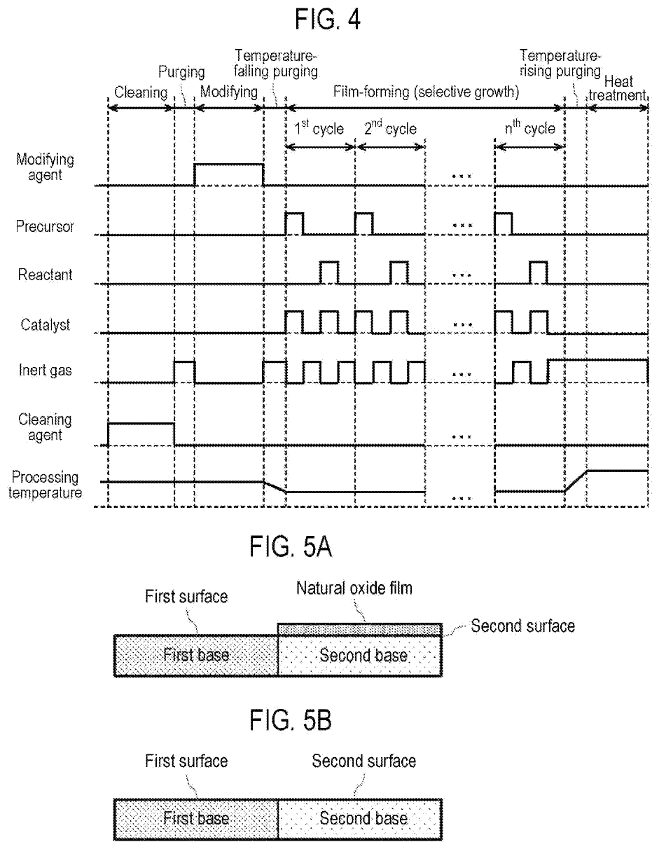

As a process of manufacturing a semiconductor device using the above-described substrate processing apparatus, an example of a method of processing a substrate, that is, a processing sequence for selectively forming a film on a second surface of a wafer 200 as a substrate among a first surface and the second surface of the wafer 200, will be described mainly with reference to FIGS. 4, 5A to 5E, and 6A to 6C. In the following description, the operations of the respective parts constituting the substrate processing apparatus are controlled by the controller 121.

The surface of the wafer 200 has a first base and a second base, the surface of the first base constitutes the first surface, and the surface of the second base constitutes the second surface. In the following description, for the sake of convenience, as a typical example, a case where the first base is a silicon oxide film (SiO₂ film, hereinafter also referred to as a SiO film) as an oxide film (for example, an oxygen-containing film) and the second base is a silicon nitride film (Si₃N₄ film, hereinafter also referred to as a SiN film) as a non-oxide film (for example, an oxygen-free film) will be described. That is, hereinafter, a case where the first surface is constituted with the surface of the SiO film as the first base and the second surface is constituted with the surface of the SiN film as the second base will be described. The first base and the second base are also referred to as a first base film and a second base film, respectively.

A processing sequence in the present embodiment includes:
a step (modifying step) of forming an inhibitor layer on the first surface of the wafer 200 having the first surface and the second surface by supplying a modifying agent to the wafer 200 to adsorb inhibitor molecules contained in the modifying agent on the first surface; and
a step (film-forming step) of forming a film on the second surface by supplying a film-forming agent containing a catalyst to the wafer 200 after forming the inhibitor layer on the first surface,
wherein the step of forming the film includes supplying, as the catalyst, a catalyst having a molecular size that is hard to pass through an inter-molecular gap of the inhibitor molecules adsorbed on the first surface.

In the following example, the film-forming agent includes a raw material, an oxidizing agent, and a catalyst. Further, in the following example, as shown in FIG. 4, the step of forming the film includes performing a cycle a predetermined number of times, the cycle including a step of supplying the raw material to the wafer 200 and a step of supplying a reactant to the wafer 200, and supplying the catalyst to the wafer 200 in at least one selected from the group of the step of supplying the raw material and the step of supplying the reactant. FIG. 4 shows, as a typical example, an example in which the catalyst is supplied in both the step of supplying the raw material and the step of supplying the reactant.

That is, FIG. 4 shows an example in which the processing sequence includes: in a non-plasma atmosphere,
a step (modifying step) of forming an inhibitor layer on a first surface of a wafer 200 having the first surface and a second surface by supplying a modifying agent to the wafer 200 to adsorb inhibitor molecules contained in the modifying agent on the first surface; and
a step (film-forming step) of forming a film on the second surface by performing a cycle a predetermined number of times (n times, where n is an integer of 1 or more), the cycle including a step of supplying a raw material and a catalyst to the wafer 200 and a step of supplying a reactant and a catalyst to the wafer 200.

In the present disclosure, for the sake of convenience, the above-described processing sequence may be denoted as follows. The same denotation may be used in modifications and other embodiments to be described later.

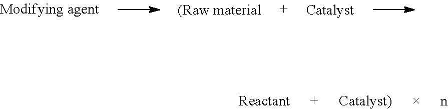

As in the processing sequences shown below, the catalyst may be supplied to the wafer 200 in one of the step of supplying the raw material and the step of supplying the reactant.

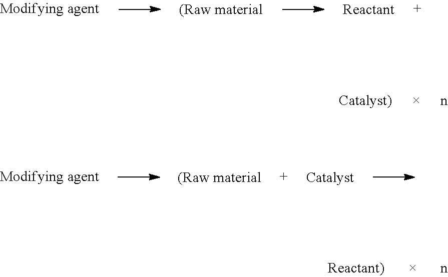

Further, as shown in FIG. 4 and the processing sequences shown below, before performing the step of forming the inhibitor layer, a step of removing a natural oxide film formed on the surface of the wafer 200 by supplying a cleaning agent to the wafer 200 may be further performed. Further, after performing the step of forming the film, a step of heat-treating the wafer 200 may be further performed.

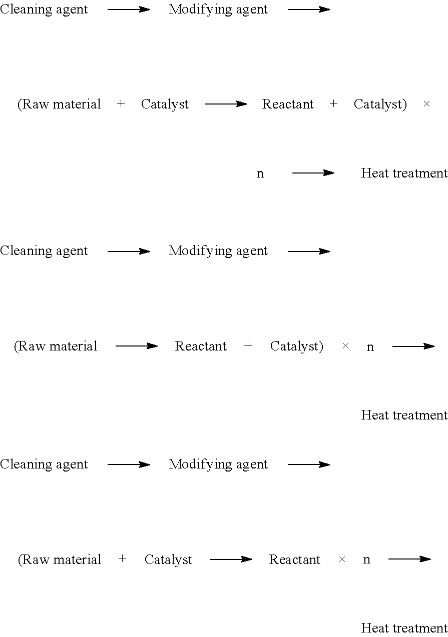

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

The term “agent” used in the present disclosure includes at least one selected from the group of a gaseous substance and a liquefied substance. The liquefied substance includes a misty substance. That is, each of the modifying agent and the film-forming agent (the raw material, the reactant, and the catalyst) may include a gaseous substance, a liquefied substance such as a misty substance, or both of them.

The term “layer” used in the present disclosure includes at least one selected from the group of a continuous layer and a discontinuous layer. For example, each of the inhibitor layer may include a continuous layer, a discontinuous layer, or both of them as long as it is possible to cause a film-forming inhibitory action.

### (Wafer Charging and Boat Loading)

After the boat 217 is charged with the plurality of wafers 200 (wafer charging), the shutter 219s is moved by the shutter opening/closing mechanism 115s and the lower end opening of the manifold 209 is opened (shutter open). Thereafter, as shown in FIG. 1, the boat 217 that supports the plurality of wafers 200 is lifted up by the boat elevator 115 to be loaded into the process chamber 201 (boat loading). In this state, the seal cap 219 seals the lower end of the manifold 209 through the O-ring 220b. Thus, the wafers 200 are prepared inside the process chamber 201.

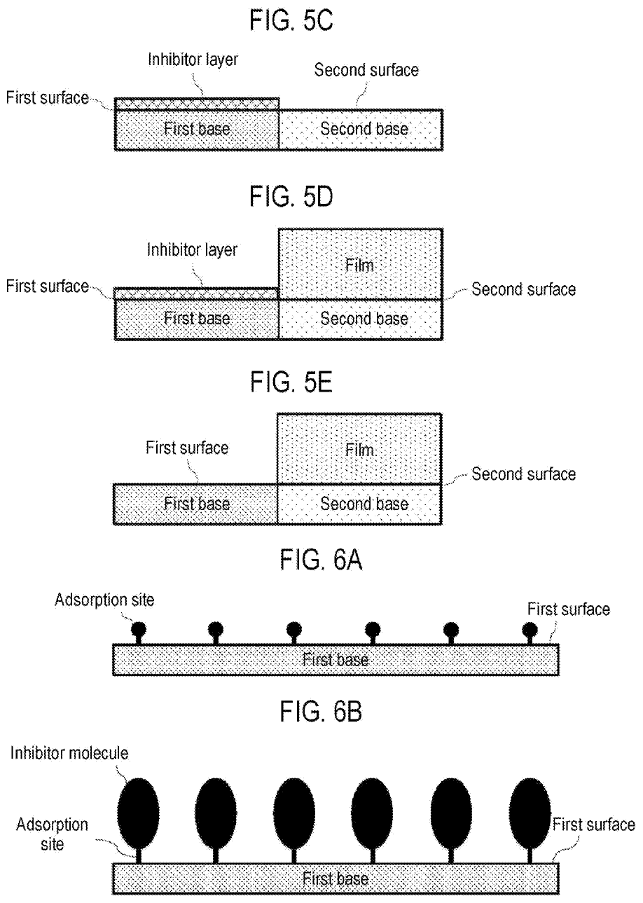

Each wafer 200 charged into the boat 217 has a first surface and a second surface, as shown in FIG. 5A. The first surface is the surface of the first base and the second surface is the surface of the second base. As described above, here, for example, a case where the first surface is the surface of a SiO film as the first base and the second surface is the surface of a SiN film as the second base will be described. Further, here, as shown in FIG. 5A, a case where a natural oxide film is formed on the second surface will be described.

### (Pressure Adjustment and Temperature Adjustment)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information. Further, the wafers 200 inside the process chamber 201 are heated by the heater 207 so as to have a desired temperature. At this time, the state of supplying electric power to the heater 207 is feedback-controlled based on the temperature information detected by the temperature sensor 263 so that the interior of the process chamber 201 has a desired temperature distribution. Further, the rotation of the wafers 200 by the rotation mechanism 267 is started. The exhaust of the interior of the process chamber 201 and the heating and rotation of the wafers 200 are continuously performed at least until the processing on the wafers 200 is completed.

### (Cleaning Step)

After that, a cleaning agent is supplied to the wafer 200.

Specifically, the valve 243e is opened to allow the cleaning agent to flow into the gas supply pipe 232e. A flow rate of the cleaning agent is adjusted by the MFC 241e, and the cleaning agent is supplied into the process chamber 201 via the gas supply pipe 232b and the nozzle 249b and is exhausted from the exhaust port 231a. In this operation, the cleaning agent is supplied to the wafer 200 from the side of the wafer 200 (cleaning agent supply). At this time, the valves 243f to 243h may be opened to allow an inert gas to be supplied into the process chamber 201 via the nozzles 249a to 249c, respectively.

By supplying the cleaning agent to the wafer 200 under the process conditions to be described later, as shown in FIG. 5B, a natural oxide film formed on the second surface of the wafer 200 may be removed (etched) to expose the second surface. At this time, as shown in FIG. 5B, the surface of the first base and the surface of the second base of the wafer 200, that is, the first surface and the second surface of the wafer 200, are exposed. When the first base is a SiO film and the second base is a SiN film, in the state where the first surface and the second surface are exposed, the first surface is OH-terminated over the entire region, and many regions of the second surface are not OH-terminated. That is, the first surface is terminated with OH groups over the entire region, and many regions of the second surface are not terminated with OH groups.

Process conditions for supplying the cleaning agent in the cleaning step are exemplified as follows.
Processing temperature: 50 to 200 degrees C., specifically 70 to 150 degrees C.
Processing pressure: 10 to 2,000 Pa, specifically 100 to 1,500 Pa
Processing time: 10 to 60 minutes, specifically 30 to 60 minutes
Flow rate of cleaning agent supplied: 0.05 to 1 slm, specifically 0.1 to 0.5 slm
Flow rate of inert gas supplied (for each gas supply pipe): 1 to 10 slm, specifically 2 to 10 slm

In this specification, the notation of a numerical range such as “50 to 200 degrees C.” means that the lower limit value and the upper limit value are included in the range. Therefore, for example, “50 to 200 degrees C.” means “50 degrees C. or higher and 200 degrees C. or lower.” The same applies to other numerical ranges. In this specification, the processing temperature means the temperature of the wafer 200 or the internal temperature of the process chamber 201, and the processing pressure means the internal pressure of the process chamber 201. Further, the processing time means the time during which a process is continued. Further, the gas supply flow rate of 0 slm means a case where no substance (gas) is supplied. These apply equally to the following description.

After removing the natural oxide film from the second surface to expose the second surface, the valve 243e is closed to stop the supply of the cleaning agent into the process chamber 201. Then, the interior of the process chamber 201 is vacuum-exhausted to remove a gaseous substance and the like remaining in the process chamber 201 from the process chamber 201. At this time, the valves 243f to 243h are opened to allow the inert gas to be supplied into the process chamber 201 via the nozzles 249a to 249c. The inert gas supplied from the nozzles 249a to 249c acts as a purge gas, whereby the interior of the process chamber 201 is purged (purging).

Process conditions for purging in the cleaning step are exemplified as follows.
Processing pressure: 1 to 30 Pa
Flow rate of inert gas supplied (for each gas supply pipe): 0.5 to 20 slm
Inert gas supply time: 1 to 120 seconds, specifically 1 to 60 seconds

The processing temperature for purging in this step is preferably the same as the processing temperature for supplying the cleaning agent.

As the cleaning agent, for example, a fluorine (F)-containing gas may be used. As the F-containing gas, for example, a chlorine trifluoride (ClF₃) gas, a chlorine fluoride (ClF) gas, a nitrogen fluoride (NF₃) gas, a hydrogen fluoride (HF) gas, a fluorine (F₂) gas, or the like may be used. Further, as the cleaning agent, for example, an acetic acid (CH₃COOH) gas, a formic acid (HCOOH) gas, a hexafluoroacetylacetone (C₅H₂F₆O₂) gas, a hydrogen (H₂) gas, or the like may be used. Further, various cleaning liquids may also be used as the cleaning agent. For example, an acetic acid aqueous solution, a formic acid aqueous solution, or the like may also be used as the cleaning agent. Further, for example, DHF cleaning may be performed using an HF aqueous solution as the cleaning agent. Further, for example, SC-1 cleaning (APM cleaning) may be performed using a cleaning liquid containing ammonia water, hydrogen peroxide water, and pure water as the cleaning agent. Further, for example, SC-2 cleaning (HPM cleaning) may be performed using a cleaning liquid containing hydrochloric acid, hydrogen peroxide water, and pure water as the cleaning agent. Further, for example, SPM cleaning may be performed using a cleaning liquid containing sulfuric acid and hydrogen peroxide water as the cleaning agent. That is, the cleaning agent may be a gaseous substance or a liquefied substance. Further, the cleaning agent may be a liquefied substance such as a misty substance. One or more of these gases and liquids may be used as the cleaning agent.

As the inert gas, a nitrogen (N₂) gas or a rare gas such as an argon (Ar) gas, a helium (He) gas, a neon (Ne) gas, or a xenon (Xe) gas may be used. One or more of these gases may be used as the inert gas. This point also applies to each step to be described later.

The cleaning step may be omitted in a case of using the wafer 200 in which the natural oxide film formed on the surface of the wafer 200 is removed in advance and the state is maintained. In this case, a modifying step to be described below is performed after the pressure adjustment and temperature adjustment.

### (Modifying Step)

After performing the cleaning step, a modifying agent is supplied to the wafer 200.

Specifically, the valve 243a is opened to allow the modifying agent to flow into the gas supply pipe 232a. A flow rate of the modifying agent is adjusted by the MFC 241a, and the modifying agent is supplied into the process chamber 201 via the nozzle 249a and is exhausted from the exhaust port 231a. In this operation, the modifying agent is supplied to the wafer 200 from the side of the wafer 200 (modifying agent supply). At this time, the valves 243f to 243h may be opened to allow an inert gas to be supplied into the process chamber 201 via the nozzles 249a to 249c, respectively.

By supplying the modifying agent to the wafer 200 under the process conditions to be described later, inhibitor molecules that are at least a portion of the molecular structure of molecules that constitute the modifying agent may be chemisorbed on the first surface of the wafer 200 to modify the first surface to form an inhibitor layer on the first surface, as shown in FIG. 5C. That is, in this step, by supplying the modifying agent, which reacts with the first surface, to the wafer 200, the inhibitor molecules contained in the modifying agent may be adsorbed on the first surface to modify the first surface to form the inhibitor layer on the first surface. This makes it possible to terminate the first surface, which is the outermost surface of the first base, with the inhibitor molecules that are at least a portion of the molecular structure of the molecules that constitute the modifying agent. The inhibitor molecules are also referred to as film-forming inhibitory molecules (adsorption inhibitory molecules or reaction inhibitory molecules). In addition, the inhibitor layer is also referred to as a film-forming inhibitory layer (adsorption inhibitory layer or reaction inhibitory layer).

The inhibitor layer formed in this step contains at least a portion of the molecular structure of the molecules that constitute the modifying agent, which are residues derived from the modifying agent. The inhibitor layer prevents adsorption of a raw material (film-forming agent) on the first surface to inhibit (suppress) progress of the film-forming reaction on the first surface in a film-forming step to be described later.

As at least the portion of the molecular structure of the molecules constituting the modifying agent, that is, as the inhibitor molecules, for example, a trialkylsilyl group such as a trimethylsilyl group (—SiMe₃) or a triethylsilyl group (—SiEt₃) may be exemplified. The trialkylsilyl group includes an alkyl group which is a kind of hydrocarbon group. In these cases, Si of the trimethylsilyl group or the triethylsilyl group is adsorbed on adsorption sites on the first surface of the wafer 200. When the first surface is the surface of a SiO film, the first surface includes an OH termination (OH group) as the adsorption sites, and Si of the trimethylsilyl group or the triethylsilyl group is bonded to O of the OH termination (OH group) on the first surface, so that the first surface is terminated by an alkyl group, which is a kind of hydrocarbon group, such as a methyl group or an ethyl group. A hydrocarbon group typified by an alkyl group (alkylsilyl group) such as a methyl group (trimethylsilyl group) or an ethyl group (triethylsilyl group), which terminates the first surface, constitutes the inhibitor layer which prevents the adsorption of the raw material (film-forming agent) on the first surface to inhibit (suppress) the progress of the film-forming reaction on the first surface in the film-forming step to be described later.

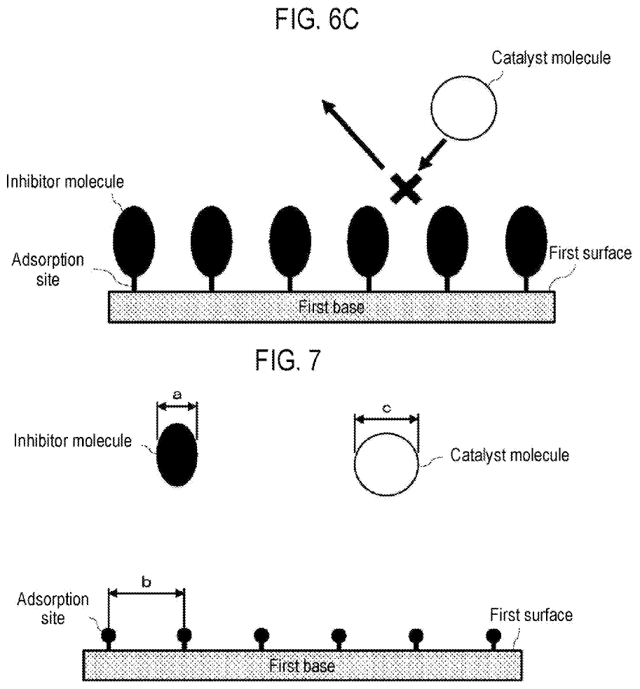

FIG. 6A shows the adsorption sites (for example, an OH group) on the first surface of the wafer 200 before supplying the modifying agent, and FIG. 6B shows a state in which inhibitor molecules are adsorbed on the adsorption sites on the first surface of the wafer 200. In the case of the above-described example, the adsorption sites on the first surface of FIG. 6A correspond to the OH group, and the inhibitor molecules adsorbed on the adsorption sites on the first surface of FIG. 6B correspond to a trialkylsilyl group such as a trimethylsilyl group (—SiMe₃) or a triethylsilyl group (—SiEt₃). That is, in this example, the inhibitor molecules contains an alkyl group (alkylsilyl group), and the inhibitor layer contains an alkyl group (alkylsilyl group) termination, that is, a hydrocarbon group termination. The alkyl group (alkylsilyl group) termination and the hydrocarbon termination are also referred to as an alkyl (alkylsilyl) termination and a hydrocarbon termination, respectively. In this example, a high film-forming inhibitory effect is obtained.

Further, in this step, at least the portion of the molecular structure of the molecules constituting the modifying agent may be adsorbed on a portion of the second surface of the wafer 200, but the adsorption amount thereof is very small and the amount of adsorption on the first surface of the wafer 200 is overwhelmingly large. Such selective (preferential) adsorption is possible because the process conditions in this step are conditions that the modifying agent does not undergo gas phase decomposition inside the process chamber 201. This is also possible because the first surface is OH-terminated over the entire region, whereas many regions of the second surface are not OH-terminated. In this step, since the modifying agent does not undergo the gas phase decomposition inside the process chamber 201, at least a portion of the molecular structure of the molecules constituting the modifying agent is not multi-deposited on the first surface and the second surface, and at least a portion of the molecular structure of the molecules constituting the modifying agent is selectively adsorbed on the first surface among the first surface and the second surface, whereby the first surface is selectively terminated with at least the portion of the molecular structure of the molecules constituting the modifying agent.

Process conditions for supplying the modifying agent in the modifying step are exemplified as follows.
Processing temperature: room temperature (25 degrees C.) to 500 degrees C., specifically room temperature to 250 degrees C.
Processing pressure: 5 to 2,000 Pa, specifically 10 to 1,000 Pa
Flow rate of modifying agent supplied: 0.001 to 3 slm, specifically 0.001 to 0.5 slm
Modifying agent supply time: 1 second to 120 minutes, specifically 30 seconds to 60 minutes
Flow rate of inert gas suppled (for each gas supply pipe): 0 to 20 slm

After selectively forming the inhibitor layer on the first surface of the wafer 200, the valve 243a is closed to stop the supply of the modifying agent into the process chamber 201. Then, a gaseous substance and the like remaining in the process chamber 201 are removed from the process chamber 201 (purging) according to the same processing procedure and process conditions as in the purging in the cleaning step. The processing temperature for purging in this step is preferably the same as the processing temperature for supplying the modifying agent.

As the modifying agent, for example, a compound having a structure in which an amino group is directly bonded to silicon (Si) or a compound having a structure in which an amino group and an alkyl group are directly bonded to silicon (Si) may be used.

Examples of the modifying agent may include (dimethylamino)trimethylsilane ((CH₃)₂NSi(CH₃)₃, abbreviation: DMATMS), (diethylamino)triethylsilane ((C₂H₅)₂NSi(C₂H₅)₃, abbreviation: DEATES), (dimethylamino)triethylsilane ((CH₃)₂NSi(C₂H₅)₃, abbreviation: DMATES), (diethylamino)trimethylsilane ((C₂H₅)₂NSi(CH₃)₃, abbreviation: DEATMS), (dipropylamino)trimethylsilane ((C₃H₇)₂NSi(CH₃)₃, abbreviation: DPATMS), (dibutylamino)trimethylsilane ((C₄H₉)₂NSi(CH₃)₃, abbreviation: DBATMS), (trimethylsilyl)amine ((CH₃)₃SiNH₂, abbreviation: TMSA), (triethylsilyl)amine ((C₂H₅)₃SiNH₂, abbreviation: TESA), (dimethylamino)silane ((CH₃)₂NSiH₃, abbreviation: DMAS), (diethylamino)silane ((C₂H₅)₂NSiH₃, abbreviation: DEAS), (dipropylamino)silane ((C₃H₇)₂NSiH₃, abbreviation: DPAS), (dibutylamino)silane ((C₄H₉)₂NSiH₃, abbreviation: DBAS), and the like. One or more of these may be used as the modifying agent.

Further, examples of the modifying agents may include bis(dimethylamino)dimethylsilane ([(CH₃)₂N]₂Si(CH₃)₂, abbreviation: BDMADMS), bis(diethylamino)diethylsilane ([(C₂H₅)₂N]₂Si(C₂H₅)₂, abbreviation: BDEADES), bis(dimethylamino)diethylsilane ([(CH₃)₂N]₂Si(C₂H₅)₂, abbreviation: BDMADES), bis(diethylamino)dimethylsilane ([(C₂H₅)₂N]₂Si(CH₃)₂, abbreviation: BDEADMS), bis(dimethylamino)silane ([(CH₃)₂N]₂SiH₂, abbreviation: BDMAS), bis(diethylamino)silane ([(C₂H₅)₂N]₂SiH₂, abbreviation: BDEAS), bis(dimethylaminodimethylsilyl)ethane ([(CH₃)₂N(CH₃)₂Si]₂C₂H₆, abbreviation: BDMADMSE), bis(dipropylamino)silane ([(C₃H₇)₂N]₂SiH₂, abbreviation: BDPAS), bis(dibutylamino)silane ([(C₄H₉)₂N]₂SiH₂, abbreviation: BDBAS), bis(dipropylamino)dimethylsilane ([(C₃H₇)₂N]₂Si(CH₃)₂, abbreviation: BDPADMS), bis(dipropylamino)diethylsilane ((C₃H₇)₂N]₂Si(C₂H₅)₂, abbreviation: BDPADES), (dimethylsilyl)diamine ((CH₃)₂Si(NH₂)₂, abbreviation: DMSDA), (diethylsilyl)diamine ((C₂H₅)₂Si(NH₂)₂, abbreviation: DESDA), (dipropylsilyl)diamine ((C₃H₇)₂Si(NH₂)₂, abbreviation: DPSDA), bis(dimethylaminodimethylsilyl)methane ([(CH₃)₂N(CH₃)₂Si]₂CH₂, abbreviation: BDMADMSM), bis(dimethylamino)tetramethyldisilane ([(CH₃)₂N]₂(CH₃)₄Si₂, abbreviation: BDMATMDS), and the like. One or more of these may be used as the modifying agent.

### (Film-Forming Step)

After performing the modifying step, a film-forming agent is supplied to the wafer 200 to form a film on the second surface of the wafer 200. That is, the film-forming agent that reacts with the second surface is supplied to the wafer 200 to selectively (preferentially) form the film on the second surface. Specifically, the following raw material supplying step and reactant supplying step are performed sequentially. In the following example, as described above, the film-forming agent includes a raw material, a reactant, and a catalysts. In the raw material supplying step and the reactant supplying step, the output of the heater 207 is adjusted so as to keep the temperature of the wafer 200 equal to or lower than the temperature of the wafer 200 in the cleaning step and the modifying step, preferably lower than the temperature of the wafer 200 in the cleaning step and the modifying step, as shown in FIG. 4.

### [Raw Material Supplying Step]

In this step, a raw material (raw material gas) and a catalyst (catalyst gas) are supplied, as a film-forming agent, to the wafer 200 subjected to the modifying step, that is, the wafer 200 with the inhibitor layer selectively formed on the first surface.

Specifically, the valves 243b and 243d are opened to allow the raw material and the catalyst to flow into the gas supply pipes 232b and 232d, respectively. The raw material and the catalyst, flow rates of which are respectively adjusted by the MFCs 241b and 241d, are supplied into the process chamber 201 via the nozzles 249b and 249a, respectively, are mixed inside the process chamber 201, and are exhausted from the exhaust port 231a. In this operation, the raw material and the catalyst are supplied to the wafer 200 from the side of the wafer 200 (raw material+catalyst supply). At this time, the valves 243f to 243h may be opened to allow an inert gas to be supplied into the process chamber 201 via the nozzles 249a to 249c, respectively.

By supplying the raw material and the catalyst to the wafer 200 under the process conditions to be described later, it is possible to selectively chemisorb at least a portion of the molecular structure of molecules constituting the raw material on the second surface while suppressing chemisorption of at least a portion of the molecular structure of molecules constituting the raw material on the first surface. As a result, a first layer is selectively formed on the second surface. The first layer includes at least a portion of the molecular structure of the molecules constituting the raw material, which is residues of the raw material. That is, the first layer contains at least some of atoms constituting the raw material.

In this step, by supplying the catalyst together with the raw material, the above-mentioned reaction may proceed in a non-plasma atmosphere and under low temperature conditions to be described later. In this way, by forming the first layer in the non-plasma atmosphere and under the low temperature conditions to be described below, it is possible to maintain the molecules and atoms constituting the inhibitor layer formed on the first surface without disappearing (desorbing) from the first surface.

Further, by forming the first layer in the non-plasma atmosphere and under the low temperature conditions to be described below, the raw material may be prevented from being thermally decomposed (gas-phase-decomposed), that is, autolyzed, inside the process chamber 201. As a result, it is possible to prevent multiple deposition of at least a portion of the molecular structure of molecules constituting the raw material on the first surface and the second surface, and selectively adsorb at least a portion of the molecular structure of molecules constituting the first raw material on the second surface among the first surface and the second surface.

Further, in this step, at least a portion of the molecular structure of the molecules constituting the raw material may be adsorbed on a portion of the first surface of the wafer 200, but the adsorption amount thereof is very small and the amount of adsorption on the second surface of the wafer 200 is overwhelmingly large. Such selective (preferential) adsorption is possible because the process conditions in this step are the low temperature conditions, as will be described later, and the conditions that the raw material does not undergo vapor phase decomposition inside the process chamber 201. Further, this is also possible because the inhibitor layer is formed over the entire region of the first surface, whereas the inhibitor layer is not formed in many regions of the second surface.

The process conditions for supplying the raw material and the catalyst in the raw material supplying step are exemplified as follows.
Processing temperature: room temperature (25 degrees C.) to 200 degrees C., specifically room temperature to 150 degrees C.
Processing pressure: 133 to 1,333 Pa
Flow rate of raw material suppled: 0.001 to 2 slm
Flow rate of catalyst supplied: 0.001 to 2 slm
Flow rate of inert gas supplied (for each gas supply pipe): 0 to 20 slm
Supply time of each gas: 1 to 120 seconds, specifically 1 to 60 seconds

After selectively forming the first layer on the second surface of the wafer 200, the valves 243b and 243d are closed to stop the supply of the raw material and the catalyst into the process chamber 201, respectively. Then, according to the same processing procedure and process conditions as in the purging in the cleaning step, a gaseous substance and the like remaining in the process chamber 201 are removed from the process chamber 201 (purging). A processing temperature for purging in this step is preferably the same as the processing temperature for supplying the raw material and the catalyst.

As the raw material, for example, a Si- and halogen-containing gas (Si- and halogen-containing substance) may be used. The halogen includes chlorine (CI), fluorine (F), bromine (Br), iodine (I), and the like. It is preferable that the Si- and halogen-containing gas contains halogen in the form of a chemical bond between Si and halogen. As the Si- and halogen-containing gas, for example, a silane-based gas having a Si—Cl bond, that is, a chlorosilane-based gas, may be used. The Si- and halogen-containing gas may further contain carbon (C), in which case it is preferable that C is contained in the form of a Si—C bond. As the Si- and halogen-containing gas, for example, a silane-based gas containing Si, Cl, and an alkylene group and having a Si—C bond, that is, an alkylenechlorosilane-based gas, may be used. The alkylene group includes a methylene group, an ethylene group, a propylene group, a butylene group, and the like. Further, as the Si- and halogen-containing gas, for example, a silane-based gas containing Si, Cl, and an alkyl group and having a Si—C bond, that is, an alkylchlorosilane-based gas, may be used. The alkyl group includes a methyl group, an ethyl group, a propyl group, a butyl group, and the like. The Si- and halogen-containing gas may further contain O, in which case it is preferable that O is contained in the form of a Si—O bond, for example, in the form of a siloxane bond (Si—O—Si bond). As the Si- and halogen-containing gas, for example, a silane-based gas having Si, Cl, and a siloxane bond, that is, a chlorosiloxane-based gas, may be used. All of these gases preferably contain Cl in the form of a Si—Cl bond. In addition to these gases, an amino group-containing gas (amino group-containing substance) such as an aminosilane-based gas may also be used as the raw material.

Examples of the raw material may include bis(trichlorosilyl)methane ((SiCl₃)₂CH₂, abbreviation: BTCSM), 1,2-bis(trichlorosilyl)ethane ((SiCl₃)₂C₂H₄, abbreviation: BTCSE), 1,1,2,2-tetrachloro-1,2-dimethyldisilane ((CH₃)₂Si₂Cl₄, abbreviation: TCDMDS), 1,2-dichloro-1,1,2,2-tetramethyldisilane ((CH₃)₄Si₂Cl₂, abbreviation: DCTMDS), 1,1,3,3-tetrachloro-1,3-disilacyclobutane (C₂H₄Cl₄Si₂, abbreviation: TCDSCB), and the like. Further, examples of the raw material may include tetrachlorosilane (SiCl₄, abbreviation: 4CS), hexachlorodisilane (Si₂Cl₆, abbreviation: HCDS), octachlorotrisilane (Si₃Cl₈, abbreviation: OCTS), and the like. Further, examples of the raw material may include hexachlorodisiloxane (Cl₃Si—O—SiCl₃, abbreviation: HCDSO), octachlorotrisiloxane (Cl₃Si—O—SiCl₂—O—SiCl₃, abbreviation: OCTSO), and the like. One or more of these may be used as the raw material.

Further, examples of the raw material may include tetrakis(dimethylamino)silane (Si[N(CH₃)₂]₄, abbreviation: 4DMAS), tris(dimethylamino)silane (Si[N(CH₃)₂]₃H, abbreviation: 3DMAS), bis(diethylamino)silane (Si[N(C₂H₅)₂]₂H₂, abbreviation: BDEAS), bis(tertiary-butylamino)silane (SiH₂[NH(C₄H₉)]₂, abbreviation: BTBAS), (diisopropylamino)silane (SiH₃[N(C₃H₇)₂], abbreviation: DIPAS), and the like. One or more of these may be used as the raw material.

As the catalyst, for example, an amine-based gas (amine-based substance) containing carbon (C), nitrogen (N), and hydrogen (H) may be used. As the amine-based gas (amine-based substance), a cyclic amine-based gas (cyclic amine-based substance) or a chain amine-based gas (chain amine-based substance) may be used. Examples of the catalyst may include cyclic amines such as pyridine (C₅H₅N), aminopyridine (C₅H₆N₂), picoline (C₆H₇N), lutidine (C₇H₉N), pyrimidine (C₄H₄N₂), quinoline (C₉H₇N), piperazine (C₄H₁₀N₂), piperidine (C₅H₁N), and aniline (C₆H₇N). Further, examples of the catalyst may include chain amines such as triethylamine ((C₂H₅)₃N, abbreviation: TEA), diethylamine ((C₂H₅)₂NH, abbreviation: DEA), monoethylamine (C₂H₅)NH₂, abbreviation: MEA), trimethylamine ((CH₃)₃N, abbreviation: TMA), dimethylamine ((CH₃)₂NH, abbreviation: DMA), and monomethylamine (CH₃NH₂, abbreviation: MMA). One or more of these may be used as the catalyst. This point also applies to the reactant supplying step to be described later.

However, it is preferable to use a catalyst having a molecular size that is hard to pass through the inter-molecular gaps of the inhibitor molecules adsorbed on the first surface. Further, as the catalyst, it is more preferable to use a catalyst having a molecular size that is hard to pass through the inter-molecular gaps of the inhibitor molecules adsorbed on the first surface to reach the first surface. Further, as the catalyst, it is more preferable to use a catalyst having a molecular size that is unable to pass through the inter-molecular gaps of the inhibitor molecules adsorbed on the first surface. Further, as the catalyst, it is even more preferable to use a catalyst having a molecular size larger than the inter-molecular gaps of the inhibitor molecules adsorbed on the first surface. That is, as the catalyst, it is preferable to select a catalyst having an appropriate molecular size based on a relationship between the inter-molecular gap of the inhibitor molecules adsorbed on the first surface and the molecular size of the catalyst molecules constituting the catalyst. This point also applies to the reactant supply step to be described later.

More specifically, for example, as shown in FIG. 7, it is preferable to satisfy c>b−a in a case where a width of an inhibitor molecule is a, an interval between the adsorption sites on the first surface (for example, an interval between OH groups) is b, and a width of a catalyst molecule is c, where a is smaller than b. For example, when a is smaller than b, it is preferable to use a catalyst having a molecular size that satisfies c>b−a.

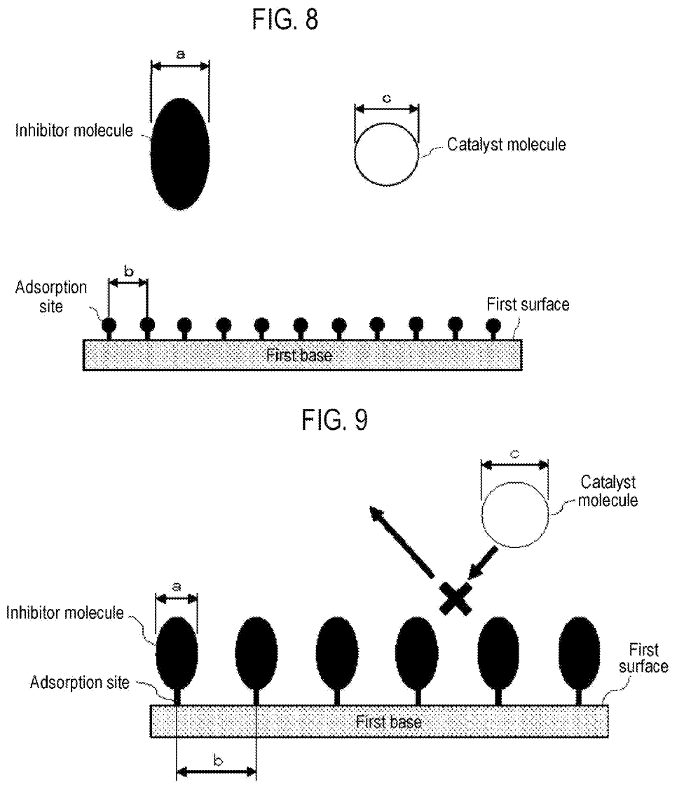

Further, for example, as shown in FIG. 8, it is preferable to satisfy c>xb−a (x is the smallest integer satisfying a<xb) in a case where the width of an inhibitor molecule is a, the interval between the adsorption sites on the first surface is b, and the width of a catalyst molecule is c, where a is larger than b. For example, when a is larger than b, it is preferable to use a catalyst having a molecular size that satisfies c>xb−a (x is the smallest integer satisfying a<xb).

That is, as the catalyst, it is preferable to select a catalyst having an appropriate molecular size based on a relationship between the width a of the inhibitor molecule, the interval b between the adsorption sites on the first surface, and the width c of the catalyst molecule.

As a result, as shown in FIG. 6C, the inhibitor molecules act as an effective steric hindrance to the catalyst molecules. This makes it possible to prevent the catalyst molecules from passing through the inter-molecular gaps of the inhibitor molecules to reach the first surface. Then, as a result, it is possible to suppress contact of the catalyst with the first surface, thereby suppressing the occurrence of a catalytic reaction on the first surface. Even if a raw material having a small molecular size passes through the inter-molecular gaps of the inhibitor molecules to reach the first surface, since the contact of the catalyst with the first surface may be suppressed, it is possible to suppress chemisorption of the raw material on the first surface. As a result, it is possible to suppress the occurrence of selective rupture. Further, since the contact of the catalyst with the first surface may be suppressed, even when using a highly reactive basic catalyst as the catalyst, the reaction between the catalyst and the first surface may be suppressed, which makes it possible to suppress the desorption of the inhibitor molecules caused by this reaction and the selective rupture associated with this reaction.

As shown in FIG. 7, when a is smaller than b, by using a catalyst having a molecular size that satisfies c>b−a, the inhibitor molecules act as an effective steric hindrance to the catalyst molecules, as shown in FIG. 9. This makes it possible to sufficiently block the catalyst molecules from passing through the inter-molecular gaps of the inhibitor molecules to reach the first surface (hereinafter, this effect is also referred to as a blocking effect). In this case, the above-mentioned effects may be more fully obtained.

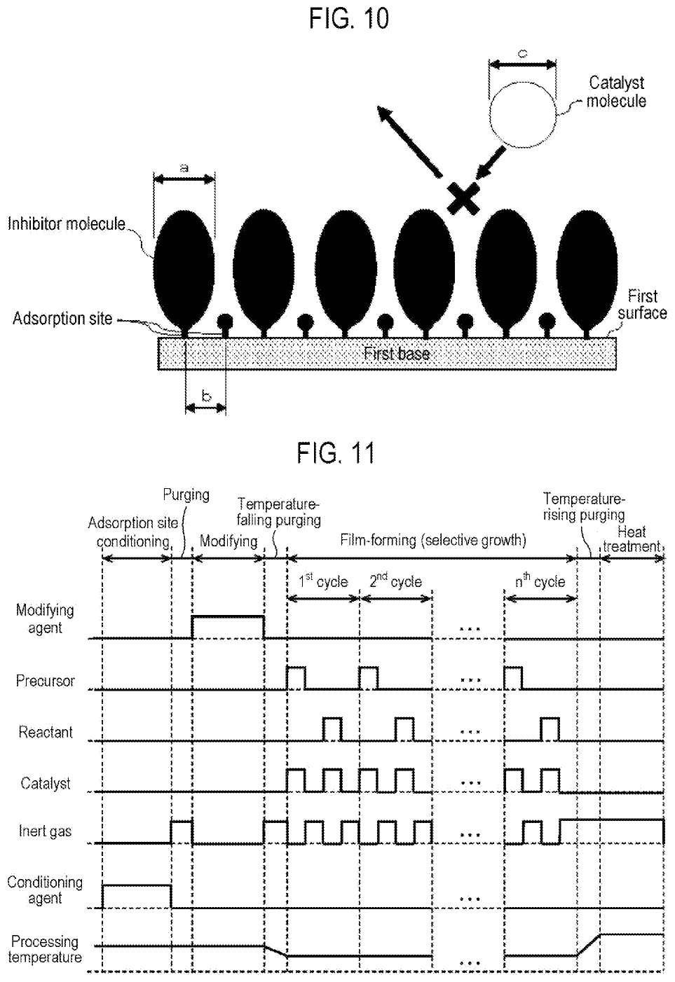

Further, as shown in FIG. 8, when a is larger than b, by using a catalyst having a molecular size that satisfies c>xb−a (x is the smallest integer that satisfies a<xb), the inhibitor molecules act as an effective steric hindrance to the catalyst molecules, as shown in FIG. 10. This makes it possible to sufficiently block the catalyst molecules from passing through the inter-molecular gaps of the inhibitor molecules to reach the first surface. In this case, the above-mentioned effects may be more fully obtained.

In the above relational expressions, the width a of the inhibitor molecule may be the maximum width of the inhibitor molecule, but is preferably an average width of the inhibitor molecule, and more preferably the minimum width of the inhibitor molecule. Further, in the above relational expressions, the width c of the catalyst molecule may be the maximum width of the catalyst molecule, but is preferably the average width of the catalyst molecule, and more preferably the minimum width of the catalyst molecule.

When the width a of the inhibitor molecule is the minimum width (minimum molecular diameter) of the inhibitor molecule and the width c of the catalyst molecule is the minimum width (minimum molecular diameter) of the catalyst molecule, the above-mentioned blocking effect is the maximum. Further, even if the width a of the inhibitor molecule is the minimum width of the inhibitor molecule and the width c of the catalyst molecule is the average width (average molecular diameter) of the catalyst molecule, the above-mentioned blocking effect is obtained sufficiently. Further, even if the width a of the inhibitor molecule is the minimum width of the inhibitor molecule and the width c of the catalyst molecule is the maximum width (maximum molecular diameter) of the catalyst molecule, the above-mentioned blocking effect is obtained sufficiently. Further, even if the width a of the inhibitor molecule is the maximum width (maximum molecular diameter) of the inhibitor molecule and the width c of the catalyst molecule is the minimum width of the catalyst molecule, the above-mentioned blocking effect is obtained sufficiently. Further, even if the width a of the inhibitor molecule is the maximum width of the inhibitor molecule and the width c of the catalyst molecule is the average width of the catalyst molecule, the above-mentioned blocking effect is obtained sufficiently. Further, even if the width a of the inhibitor molecule is the maximum width of the inhibitor molecule and the width c of the catalyst molecule is the maximum width of the catalyst molecule, the above-mentioned blocking effect is obtained to some extent.

### [Reactant Supplying Step]

After the raw material supplying step is completed, a reactant (reaction gas) and a catalyst (catalyst gas) are supplied, as a film-forming agent, to the wafer 200, that is, the wafer 200 with the first layer selectively formed on the second surface. Here, an example in which an oxidizing agent (oxidizing gas) is used as the reactant (reaction gas) will be described.

Specifically, the valves 243c and 243d are opened to allow the reactant and the catalyst to flow into the gas supply pipes 232c and 232d, respectively. Flow rates of the reactant and the catalyst are adjusted by the MFCs 241c and 241d, respectively, and the reactant and the catalyst are supplied into the process chamber 201 via the nozzles 249c and 249a, respectively, are mixed inside the process chamber 201, and are exhausted from the exhaust port 231a. In this operation, the reactant and the catalyst are supplied to the wafer 200 from the side of the wafer 200 (reactant+catalyst supply). At this time, the valves 243f to 243h may be opened to allow an inert gas to be supplied into the process chamber 201 via the nozzles 249a to 249c, respectively.

By supplying the reactant and the catalyst to the wafer 200 under the process conditions to be described later, it is possible to oxidize at least a portion of the first layer formed on the second surface of the wafer 200 in the raw material supplying step. As a result, a second layer formed by oxidizing the first layer is formed on the second surface.

In this step, by supplying the catalyst together with the reactant, the above-mentioned reaction may proceed in a non-plasma atmosphere and under low temperature conditions to be described later. In this way, by forming the second layer in the non-plasma atmosphere and under the low temperature conditions to be described below, it is possible to maintain the molecules and atoms constituting the inhibitor layer formed on the first surface without disappearing (desorbing) from the first surface.

Process conditions for supplying the reactant and the catalyst in the reactant supplying step are exemplified as follows.
Processing temperature: room temperature (25 degrees C.) to 200 degrees C., specifically room temperature to 150 degrees C.
Processing pressure: 133 to 1,333 Pa
Flow rate of reactant supplied: 0.001 to 2 slm
Flow rate of catalyst supplied: 0.001 to 2 slm
Flow rate of inert gas supplied (for each gas supply pipe): 0 to 20 slm
Supply time of each gas: 1 to 120 seconds, specifically 1 to 60 seconds

After oxidizing the first layer formed on the second surface to change (convert) the first layer into the second layer, the valves 243c and 243d are closed to stop the supply of the reactant and the catalyst into the process chamber 201, respectively. Then, according to the same processing procedure and process conditions as in the purging in the cleaning step, a gaseous substance and the like remaining in the process chamber 201 are removed from the process chamber 201 (purging). A processing temperature for purging in this step is preferably the same as the processing temperature for supplying the reactant and the catalyst.

As the reactant, that is, the oxidizing agent, for example, an oxygen (O)- and hydrogen (H)-containing gas (O- and H-containing substance) may be used. Examples of the O- and H-containing gas may include water vapor (H₂O gas), a hydrogen peroxide (H₂O₂) gas, a hydrogen (H₂) gas+oxygen (O₂) gas, a H₂ gas+ozone (O₃) gas, and the like. That is, as the O- and H-containing gas, an O-containing gas+H-containing gas may be used. Even in this case, as the H-containing gas, a deuterium (D₂) gas may be used instead of a H₂ gas. One or more of these gases may be used as the reactant.

In the present disclosure, the description of two gases such as “H₂ gas+O₂ gas” together means a mixed gas of the H₂ gas and the O₂ gas. When supplying the mixed gas, the two gases may be mixed (pre-mixed) inside a supply pipe and then supplied into the process chamber 201, or the two gases may be supplied separately from different supply pipes into the process chamber 201 and then mixed (post-mixed) inside the process chamber 201.

Further, as the reactant, that is, the oxidizing agent, in addition to the O- and H-containing gas, an O-containing gas (O-containing substance) may be used. Examples of the O-containing gas may include an O₂ gas, an O₃ gas, a nitrous oxide (N₂O) gas, a nitric oxide (NO) gas, a nitrogen dioxide (NO₂) gas, a carbon monoxide (CO) gas, a carbon dioxide (CO₂) gas, and the like. As the reactant, that is, the oxidizing agent, in addition to these gases, the above-mentioned various aqueous solutions and various cleaning liquids may also be used. In this case, by exposing the wafer 200 to an aqueous solution or a cleaning liquid, an object to be oxidized on the surface of the wafer 200 may be oxidized. One or more of these may be used as the reactant.

As the catalyst, for example, the same catalysts as the various catalysts exemplified in the above-described raw material supplying step may be used. Further, also in the reactant supplying step, it is preferable to select a catalyst having a molecular size that allows the above-mentioned blocking effect to be obtained.

### [Performing Cycle Predetermined Number of Times]

By performing a cycle a predetermined number of times (n times, where n is an integer of 1 or more), the cycle including non-simultaneously, that is, alternately without synchronization, performing the above-described raw material supplying step and reactant supplying step alternately, a film may be selectively (preferentially) formed on the second surface among the first surface and the second surface of the wafer 200, as shown in FIG. 5D. For example, when the above-described raw material, reactant, and catalyst are used, a silicon oxycarbide film (SiOC film) or a silicon oxide film (SiO film) may be selectively grown as a film on the second surface. The above cycle is preferably repeated a plurality of times. That is, a thickness of the second layer formed per cycle may be set to be smaller than a desired film thickness, and the above cycle may be repeated a plurality of times until a thickness of a film formed by stacking second layers reaches the desired film thickness.

As described above, by performing the above cycle a predetermined number of times, the film may be selectively grown on the second surface of the wafer 200. At this time, since the inhibitor layer is formed on the first surface of the wafer 200, it is possible to suppress the growth of the film on the first surface. That is, by performing the above cycle a predetermined number of times, it is possible to promote the growth of the film on the second surface while suppressing the growth of the film on the first surface.

Further, when the raw material supplying step and reactant supplying step are performed, since the inhibitor layer formed on the first surface is maintained on the first surface as described above, it is possible to suppress the growth of the film on the first surface. However, when the formation of the inhibitor layer on the first surface is insufficient for some reason, the formation and growth of the film on the first surface may occur very slightly. However, even in this case, the thickness of the film formed on the first surface is much thinner than the thickness of the film formed on the second surface. In the present disclosure, “high selectivity in selective growth” means to include not only a case where a film is formed only on the surface of the second surface with no film formed on the first surface, but also a case where a very thin film is formed on the first surface, but a much thicker film is formed on the second surface.

### (Heat-Treating Step)

After performing the film-forming step, heat treatment is performed on the wafer 200 after selectively forming the film on the second surface. At this time, the output of the heater 207 is adjusted so that an internal temperature of the process chamber 201, that is, a temperature of the wafer 200 after selectively forming the film on the second surface, is set to be equal to or higher than the temperature of the wafer 200 in the cleaning step, the modifying step, and the film-forming step, preferably higher than the temperature of the wafer 200 in these steps.

By performing the heat treatment (annealing treatment) on the wafer 200, impurities contained in the film formed on the second surface of the wafer 200 in the film-forming step may be removed, defects may be repaired, and the film may be made harder. By hardening the film, the processing resistance, that is, the etching resistance, of the film may be improved. In a case where the film formed on the second surface does not require removal of impurities, repair of defects, hardening of the film and the like, the annealing treatment, that is, the heat treatment step, may be omitted.

Further, according to this step, the inhibitor layer remaining on the first surface of the wafer 200 may be heat-treated (annealed) after the film-forming step is performed. As a result, at least a portion of the inhibitor layer remaining on the first surface may be desorbed and/or invalidated. The invalidation of the inhibitor layer means changing the molecular structure of molecules, the arrangement structure of atoms and the like, which constitute the inhibitor layer, thereby enabling the adsorption of the film-forming agent on the first surface and the reaction between the first surface and the film-forming agent.

By performing this step as described above, as shown in FIG. 5E, the film formed on the second surface of the wafer 200 is hardened by the heat treatment, and at least a portion of the inhibitor layer formed on the first surface of the wafer 200 is desorbed and/or invalidated. That is, by performing this step, the heat-treated film is present on the second surface, and at least a portion of the first surface is exposed. FIG. 5E shows an example in which the inhibitor layer formed on the first surface is desorbed and removed to expose the first surface.

This step may be performed in a state where an inert gas is supplied into the process chamber 201, or may be performed in a state where a reactive substance such as an oxidizing agent (oxidizing gas) is supplied into the process chamber 201. In this case, the inert gas and the reactive substance such as the oxidizing agent (oxidizing gas) are also referred to as an assist substance.

Process conditions for the heat treatment in the heat-treating step are exemplified as follows.
Processing temperature: 200 to 1,000 degrees C., specifically 400 to 700 degrees C.
Processing pressure: 1 to 120,000 Pa
Processing time: 1 to 18,000 seconds
Flow rate of assist substance supplied: 0 to 50 slm

### (After-Purging and Returning to Atmospheric Pressure)

After the heat-treating step is completed, an inert gas acting as a purge gas is supplied into the process chamber 201 from each of the nozzles 249a to 249c and is exhausted from the exhaust port 231a. Thus, the interior of the process chamber 201 is purged, and a gas, reaction by-products, and the like remaining in the process chamber 201 are removed from the process chamber 201 (after-purging). After that, the internal atmosphere of the process chamber 201 is substituted with an inert gas (inert gas substitution) and the internal pressure of the process chamber 201 is returned to the atmospheric pressure (returning to atmospheric pressure).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter close). The processed wafers 200 are unloaded from the reaction tube 203 and are then discharged from the boat 217 (wafer discharging).

The cleaning step, the modifying step, the film-forming step, and the heat-treating step are preferably performed in the same process chamber (in-situ). As a result, after the surface of the wafer 200 is cleaned by the cleaning step (after the natural oxide film is removed), the modifying step, the film-forming step, and the heat-treating step may be performed without exposing the wafer 200 to the atmosphere, that is, while the surface of the wafer 200 is kept clean, which makes it possible to appropriately perform the selective growth. That is, by performing these steps inside the same process chamber, it is possible to perform the selective growth with high selectivity. In a case where the cleaning step may be omitted as described above, it is preferable to perform the modifying step, the film-forming step, and the heat-treating step inside the same process chamber. Further, in a case where the heat-treating step may be omitted as described above, it is preferable to perform the modifying step and the film-forming step inside the same process chamber.

### (3) Effects of the Present Embodiment

According to the present embodiment, one or more effects set forth below may be achieved.

In the film-forming step, by supplying, to the wafer 200, a catalyst having a molecular size that is hard to pass through the inter-molecular gaps of the inhibitor molecules adsorbed on the first surface, the inhibitor molecules act as an effective steric hindrance to the catalyst molecules. This makes it possible to prevent the catalyst molecules from passing through the inter-molecular gaps of the inhibitor molecules to reach the first surface. Then, as a result, it is possible to suppress contact of the catalyst with the first surface, thereby suppressing the occurrence of a catalytic reaction on the first surface. Even if a raw material or a reactant having a small molecular size passes through the inter-molecular gaps of the inhibitor molecules to reach the first surface, since the contact of the catalyst with the first surface may be suppressed, it is possible to suppress chemisorption of the raw material on the first surface and oxidation of the first surface by the reactant. As a result, it is possible to suppress the occurrence of selective rupture. Further, since the contact of the catalyst with the first surface may be suppressed, even when using a highly reactive basic catalyst as the catalyst, the reaction between the catalyst and the first surface may be suppressed, which makes it possible to suppress the desorption of the inhibitor molecules caused by this reaction and the selective rupture associated with this reaction.

As the catalyst, it is more preferable to use a catalyst having a molecular size that is hard to pass through the inter-molecular gaps of the inhibitor molecules to reach the first surface. Further, as the catalyst, it is more preferable to use a catalyst having a molecular size that is unable to pass through the inter-molecular gaps of the inhibitor molecules. Further, as the catalyst, it is even more preferable to use a catalyst having a molecular size larger than the inter-molecular gaps of the inhibitor molecules. In these cases, the above-described effects may be more fully obtained.

Further, in the film-forming step, when a catalyst having a molecular size that easily passes through the inter-molecular gaps of the inhibitor molecules adsorbed on the first surface is supplied to the wafer 200, the effect of the inhibitor molecule as a steric hindrance on the catalyst molecules is reduced, so that the above-described effects cannot be obtained.

By satisfying c>b−a in a case where the width of an inhibitor molecule is a, the interval between the adsorption sites on the first surface is b, and the width of a catalyst molecule is c, where a is smaller than b, for example, by using a catalyst having a molecular size that satisfies c>b−a, the inhibitor molecules may act as an effective steric hindrance to the catalyst molecules. This makes it possible to sufficiently block the catalyst molecules from passing through the inter-molecular gap of the inhibitor molecules to reach the first surface. In this case, the above-described effects may be more fully obtained.

Further, in a case where a is smaller than b, when a catalyst having a molecular size that satisfies c≤b−a is used, the effect of the inhibitor molecule as a steric hindrance on the catalyst molecules is reduced, so that the above-described blocking effect becomes insufficient.

By satisfying c>xb−a (x is the smallest integer that satisfies a<xb) in a case where the width of an inhibitor molecule is a, the interval between the adsorption sites on the first surface is b, and the width of a catalyst molecule is c, where a is larger than b, for example, by using a catalyst having a molecular size that satisfies c>xb−a (x is the smallest integer that satisfies a<xb), the inhibitor molecules may act as an effective steric hindrance to the catalyst molecules. This makes it possible to sufficiently block the catalyst molecules from passing through the inter-molecular gaps of the inhibitor molecules to reach the first surface. In this case, the above-described effects may be more fully obtained.

Further, in a case where a is larger than b, when a catalyst having a molecular size that satisfies c≤xb−a is used, the effect of the inhibitor molecule as a steric hindrance on the catalyst molecules is reduced, so that the above-described blocking effect becomes insufficient.

In the film-forming step, by performing a cycle a predetermined number of times, the cycle including alternately performing the raw material supplying step and the reactant supplying step, and supplying the catalyst to the wafer 200 in at least one selected from the group of the raw material supplying step and the reactant supplying step, it is possible to perform selective growth with good controllability under the above-mentioned low temperature conditions.

The above-described effects may be achieved similarly even when a predetermined substance (gaseous substance or liquefied substance) is arbitrarily selected and used from the above-mentioned various cleaning agents, various modifying agents, various raw materials, various reactants, various catalysts, and various inert gases.

### (4) Modifications

The processing sequence in the present embodiment may be changed as in the following modifications. These modifications may be used in proper combination. Unless otherwise stated, the processing procedures and process conditions in each step of each modification may be the same as the processing procedures and process conditions in each step of the above-described processing sequence.

### Modification 1

As shown in FIG. 11 and the processing sequences shown below, by supplying a regulating agent to the wafer 200 before performing the modifying step, that is, before performing the step of forming the inhibitor layer, a step of regulating at least one selected from the group of the interval and density of the adsorption sites on the first surface of the wafer 200 (adsorption-site regulating step) may be performed.

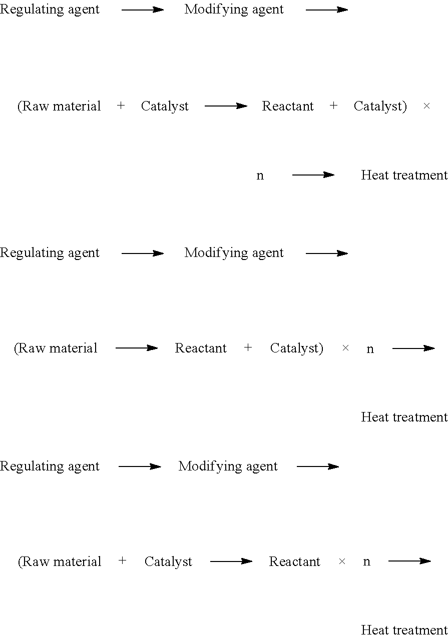

In this case, the cleaning step may be further performed before performing the adsorption-site regulating step.

In the adsorption-site regulating step, the regulating agent may be supplied to the wafer 200 from a regulating agent supply system. By supplying the regulating agent to the wafer 200 under the process conditions to be described later, at least one selected from the group of the interval and density of the adsorption sites on the first surface of wafer 200 may be regulated. For example, the interval (density) of the adsorption sites on the first surface may be made relatively sparse as shown in FIG. 7, or relatively dense as shown in FIG. 8. Thereafter, the modifying step, the film-forming step, and the heat-treating step may be performed in the same manner as in the above-described embodiment. In the same manner as in the above-described embodiment, in a case where the film formed on the second surface in the film-forming step does not require removal of impurities, repair of defects, hardening of the film and the like, the heat-treating step may also be omitted.

Process conditions for supplying the regulating agent in the adsorption-site regulating step are exemplified as follows.
Processing temperature: 100 to 400 degrees C., specifically 200 to 350 degrees C.
Processing pressure: 1 to 101,325 Pa, specifically 1 to 13,300 Pa
Processing time: 1 to 240 minutes, specifically 30 to 120 minutes
Flow rate of regulating agent supplied: 0 to 20 slm
Flow rate of inert gas supplied (for each gas supply pipe): 1 to 20 slm, specifically 2 to 10 slm

It is also possible to adjust at least one selected from the group of the interval and density of the adsorption sites on the first surface by the heat treatment (annealing treatment) alone without supplying the regulating agent, and the flow rate of the above-mentioned regulating agent supplied of 0 slm shows such a case. When regulating the adsorption sites on the first surface by the annealing treatment, an inert gas may be supplied, in which case the supplied inert gas may be also referred to as a regulating agent. The regulation of the adsorption sites on the first surface by the annealing treatment may be performed such that, for example, the higher the processing temperature, the higher the processing pressure, or the longer the processing time, the sparser the interval (density) of the adsorption sites on the first surface. Further, in this case, the adsorption sites may be regulated such that, for example, the lower the processing temperature, the lower the processing pressure, or the shorter the processing time, the denser the interval (density) of the adsorption sites on the first surface. In this way, by the annealing treatment, the interval (density) of the adsorption sites on the first surface may be regulated with good controllability.

As the regulating agent, for example, at least one selected from the group of the above-mentioned various inert gases, various cleaning agents, and various oxidizing agents may be used. The regulating agent may be a gaseous substance or a liquefied substance. Further, the regulating agent may be a liquefied substance such as a misty substance. One or more of these may be used as the regulating agent.

When an O- and H-containing gas as an oxidizing agent or an O- and H-containing substance such as various aqueous solutions and various cleaning liquids is used as the regulating agent, it is possible to increase the density of OH terminations (OH groups) on the first surface, so that the interval (density) of the adsorption sites on the first surface may be regulated to be dense. That is, by oxidation treatment, the interval (density) of the adsorption sites on the first surface may be adjusted to be dense. Further, as will be described later, even when a H-containing gas (H-containing substance) as a reducing agent is used as the regulating agent, it is possible to increase the density of OH terminations on the first surface, so that the interval (density) of the adsorption sites on the first surface may be regulated to be dense. That is, by reduction treatment, the interval (density) of the adsorption sites on the first surface may be also regulated to be dense.

On the other hand, when an O- and H-free substance or a H-free substance is used as the regulating agent, it is possible to decrease the density of OH terminations (OH groups) on the first surface, so that the interval (density) of the adsorption sites may be regulated to be sparse. In this way, by exposure of the O- and H-containing substance or the H-containing substance to the first surface or by exposure of the O- and H-free substance or the H-free substance to the first surface, the interval (density) of the adsorption sites on the first surface may be regulated with good controllability.

Further, by sequentially or alternately performing a process using the O- and H-containing substance or the H-containing substance as the regulating agent and a process using the O- and H-free substance or the H-free substance as the regulating agent, fine regulating of each of the above-described controls becomes possible. In this case, by controlling each process condition, it is possible to control the balance of a degree of regulation in each process, which makes it possible to make one of these regulations predominant. This makes it possible to regulate the interval (density) of the adsorption sites on the first surface with better controllability. For example, by sequentially or alternately performing the process using the O- and H-containing substance as the regulating agent and the annealing treatment, it is possible to regulate the interval (density) of the adsorption sites on the first surface with better controllability.

Further, when a cleaning agent is used as the regulating agent, at least one selected from the group of the interval and density of the adsorption sites on the first surface may be regulated together with removal of the natural oxide film formed on the second surface. That is, the removal of the natural oxide film on the second surface and the regulation of the adsorption sites on the first surface may be performed in parallel, that is, simultaneously and together. The removal of the natural oxide film formed on the second surface by the cleaning agent corresponds to an etching process. At this time, a portion of the first surface may be etched. That is, the cleaning process is also one type of etching process. By this etching process, the interval (density) of the adsorption sites on the first surface may be regulated to be sparse. On the other hand, when the cleaning agent contains an O- and H-containing substance such as an aqueous solution or a cleaning liquid, the interval (density) of the adsorption sites on the first surface may be regulated to be dense. By controlling the process conditions in the cleaning process, it is possible to control the balance between these regulations, which makes it possible to make one of these regulations predominant. This makes it possible to regulate the interval (density) of the adsorption sites on the first surface with good controllability.

Further, a reducing agent (H-containing substance) may be used as the regulating agent. That is, by reduction treatment, the interval (density) of the adsorption sites on the first surface may be regulated. As the reducing agent, for example, a H₂ gas or a D₂ gas may be used. By using the reducing agent as the regulating agent, it is possible to increase the density of OH terminations on the first surface, so that the interval (density) of the adsorption sites on the first surface may be regulated to be dense.

Further, the above-mentioned various regulating agents may be plasma-excited and used as the regulating agent. That is, the interval (density) of the adsorption sites on the first surface may be regulated by plasma treatment. In this case, various active species generated by plasma excitation of the above-mentioned various regulating agents are supplied to the first surface. For example, when an O- and H-containing substance or a H-containing substance is plasma-excited and used as the regulating agent, it is possible to increase the density of OH terminations on the first surface, so that the interval (density) of the adsorption sites on the first surface may be regulated to be dense. On the other hand, when an O- and H-free substance or a H-free substance is plasma-excited and used as the regulating agent, it is possible to decrease the density of OH terminations on the first surface, so that the interval (density) of the adsorption sites may be regulated to be sparse. In this way, even when plasma-exciting and using the above-mentioned various regulating agents, the interval (density) of the adsorption sites on the first surface may be regulated with good controllability.

In this way, the interval (density) of the adsorption sites on the first surface may be regulated with good controllability by at least one selected from the group of the heat treatment, the cleaning treatment, the etching treatment, the reduction treatment, the oxidation treatment, the exposure of the first surface to the O- and H-containing substance, and the plasma treatment. Further, by using at least two or more of these various treatments in combination, the above-described various controls may be finely regulated, which makes it possible to regulate the interval (density) of the adsorption sites on the first surface with better controllability.

Also in this modification, the same effects as those of the above-described embodiment may be obtained. Further, according to this modification, by regulating the interval (density) of the adsorption sites on the first surface in the adsorption-site regulating step, it is possible to freely regulate the inter-molecular gaps of the inhibitor molecules to be adsorbed on the first surface in the modifying step. This makes it possible to increase a degree of freedom in combination of the type of modifying agent used in the modifying step and the type of catalyst used in the film-forming step. That is, it is possible to increase the degree of freedom in the type of modifying agent used in the modifying step and the degree of freedom in the type of catalyst used in the film-forming step.

### Modification 2

When processing the wafer 200 according to the processing sequence of Modification 1, as shown in FIG. 7, it is preferable to satisfy c>b−a in a case where the width of an inhibitor molecule is a, the interval between the adsorption sites on the first surface is b, and the width of a catalyst molecule constituting the catalyst is c, where b is regulated to be larger than a in the adsorption-site regulating step. In this case, it is preferable to regulate the interval (density) of the adsorption sites on the first surface so as to satisfy, for example, b>a and c>b−a. Further, it is preferable to regulate the interval (density) of the adsorption sites on the first surface and select the type of catalyst so as to satisfy, for example, b>a and c>b−a. Further, it is preferable to regulate the interval (density) of the adsorption sites on the first surface and select the type of modifying agent so as to satisfy, for example, b>a and c>b−a. Further, it is preferable to regulate the interval (density) of the adsorption sites on the first surface and select the type of catalyst and the type of modifying agent so as to satisfy, for example, b>a and c>b−a.

By doing so, as shown in FIG. 9, the inhibitor molecules act as an effective steric hindrance to the catalyst molecules. This makes it possible to sufficiently block the catalyst molecules from passing through the inter-molecular gaps of the inhibitor molecules to reach the first surface. In this case, the effects of Modification 2 may be more fully obtained. Further, also in this case, it is possible to increase a degree of freedom in combination of the type of modifying agent and the type of catalyst.

### Modification 3

When processing the wafer 200 according to the processing sequence of Modification 1, as shown in FIG. 8, it is preferable to satisfy c>xb−a (x is the smallest integer satisfying a<xb) in a case where the width of an inhibitor molecule is a, the interval between the adsorption sites on the first surface is b, and the width of a catalyst molecule constituting the catalyst is c, where b is regulated to be smaller than a in the adsorption-site regulating step. In this case, it is preferable to regulate the interval (density) of the adsorption sites on the first surface so as to satisfy, for example, b<a and c>xb−a. Further, it is preferable to regulate the interval (density) of the adsorption sites on the first surface and select the type of catalyst so as to satisfy, for example, b<a and c>xb−a. Further, it is preferable to regulate the interval (density) of the adsorption sites on the first surface and select the type of modifying agent so as to satisfy, for example, bra and c>xb−a. Further, it is preferable to regulate the interval (density) of the adsorption sites on the first surface and select the type of catalyst and the type of modifying agent so as to satisfy, for example, b<a and c>xb−a.

By doing so, as shown in FIG. 10, the inhibitor molecules act as an effective steric hindrance to the catalyst molecules. This makes it possible to sufficiently block the catalyst molecules from passing through the inter-molecular gaps of the inhibitor molecules to reach the first surface. In this case, the effects of Modification 3 may be more fully obtained. Further, also in this case, it is possible to increase the degree of freedom in combination of the type of modifying agent and the type of catalyst.

### Other Embodiments of the Present Disclosure

The embodiments of the present disclosure have been specifically described above. However, the present disclosure is not limited to the above-described embodiments, and various changes may be made without departing from the gist thereof.

For example, the wafer 200 may include at least one selected from the group of an oxygen-containing film and a metal-containing film as the first surface (the first base), and may include at least one selected from the group of an oxygen-free film and a metal-free film as the second surface (the second base). Further, for example, the wafer 200 may have a plurality of types of regions having different materials as the first surface (the first base), and may have a plurality of types of regions having different materials as the second surface (the second base). The regions constituting the first surface and the second surface may include, in addition to the above-mentioned SiO film and SiN film, films containing semiconductor elements, such as a silicon oxycarbonitride film (SiOCN film), a silicon oxycarbide film (SiOC film), a silicon oxynitride film (SiON film), a silicon carbonitride film (SiCN film), a silicon carbide film (SiC film), a silicon borocarbonitride film (SiBCN film), a silicon boronitride film (SiBN film), a silicon borocarbide film (SiBC film), a silicon film (Si film), a germanium film (Ge film), and a silicon germanium film (SiGe film), films containing metal elements, such as a titanium nitride film (TiN film), a tungsten film (W film), a molybdenum film (Mo film), a ruthenium film (Ru film), a cobalt film (Co film), a nickel film (Ni film), and a copper film (Cu film), an amorphous carbon film (a-C film), a single crystal Si (Si wafer), and the like. Any region may be used as the first surface as long as it is a region in which an inhibitor layer may be formed. On the other hand, any region may be used as the second surface as long as it is a region on which an inhibitor layer is difficult to be formed. This embodiment may also provide the same effects as those of the above-described embodiments.

Further, for example, in the selective growth, in addition to the SiOC film and the SiO film, films containing semiconductor elements such as a SiON film, a SiOCN film, a SiCN film, a SiC film, a SiN film, a SiBCN film, a SiBN film, a SiBC film, a Si film, a Ge film, a SiGe film or the like, and films containing metal elements such as a TiN film, a W film, a WN film, a Mo film, a Ru film, a Co film, a Ni film, an Al film, an AlN film, a TiO film, a WO film, a WON film, a MoO film, a RuO film, a CoO film, a NiO film, an AlO film, a ZrO film, a HfO film, a TaO film or the like, may be formed. Even when forming these films, the same effects as those of the above-described embodiments may be obtained.

Recipes used in each process may be prepared individually according to the processing contents and may be stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for a single substrate processing apparatus to form films of various kinds, composition ratios, qualities, and thicknesses with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

An example in which a film is formed using a batch-type substrate processing apparatus capable of processing a plurality of substrates at a time has been described in the above-described embodiments. The present disclosure is not limited to the above-described embodiments, but may be suitably applied, for example, to a case where a film is formed using a single-wafer type substrate processing apparatus capable of processing a single substrate or several substrates at a time. In addition, an example in which a film is formed using a substrate processing apparatus provided with a hot-wall-type process furnace has been described in the above-described embodiments. The present disclosure is not limited to the above-described embodiments, but may be suitably applied to a case where a film is formed using a substrate processing apparatus provided with a cold-wall-type process furnace.

Even in the case of using these substrate processing apparatuses, each process may be performed according to the same processing procedures and process conditions as those in the above-described embodiments and modifications, and the same effects as those of the above-described embodiments and modifications may be obtained.

The above-described embodiments and modifications may be used in proper combination. The processing procedures and process conditions used in this case may be the same as, for example, the processing procedures and process conditions in the above-described embodiments and modifications.

### EXAMPLES

### Example 1

An evaluation sample 1 of Example 1 was prepared by performing the processing sequence of the above-described Modification 1 on a wafer having the same first surface and second surface as the above-described embodiment to form a SiOC film on the second surface. When preparing the evaluation sample 1, adsorption sites on the first surface were regulated by the annealing treatment, and a modifying agent and a catalyst that satisfy b<a and c>xb−a (x is the smallest integer that satisfies a<xb) were used. a, b, and c are as explained in the above-described embodiment. The process conditions in each step when preparing the evaluation sample 1 were set to predetermined conditions within the range of the process conditions in each step of the above-described embodiment. In the annealing treatment for adsorption site regulation, the processing temperature was set to 300 to 350 degrees C.

### Example 2

An evaluation sample 2 of Example 2 was prepared by performing the processing sequence of the above-described Modification 1 on a wafer having the same first surface and second surface as the above-described embodiment to form a SiOC film on the second surface. When preparing the evaluation sample 2, adsorption sites on the first surface were regulated by the annealing treatment, and a modifying agent and a catalyst that satisfy b>a and c>b−a were used. a, b, and c are as explained in the above-described embodiment. The process conditions in each step when preparing the evaluation sample 2 were the same as the process conditions in each step when preparing the evaluation sample 1 except for the process conditions (processing time) in the annealing treatment for adsorption site regulation. In the annealing treatment for adsorption site regulation, the processing temperature was set to 300 to 350 degrees C., and the processing time was set to be longer than the processing time when preparing the evaluation sample 1.

### Comparative Example 1

An evaluation sample 3 of Comparative Example 1 was prepared by performing the processing sequence of the above-described Modification 1 on a wafer having the same first surface and second surface as the above-described embodiment to form a SiOC film on the second surface. When preparing the evaluation sample 3, adsorption sites on the first surface were regulated by the annealing treatment, and a modifying agent and a catalyst that satisfy bra and c≤xb−a (x is the smallest integer that satisfies a<xb) were used. a, b, and c are as explained in the above-described embodiment. The process conditions in each step when preparing the evaluation sample 3 were the same as the process conditions in each step when preparing the evaluation sample 1 except for the process conditions (processing temperature) in the annealing treatment for adsorption site regulation. In the annealing treatment for adsorption site regulation, the processing temperature was set to 450 to 500 degrees C.

### Comparative Example 2

An evaluation sample 4 of Comparative Example 2 was prepared by performing the processing sequence of the above-described Modification 1 on a wafer having the same first surface and second surface as the above-described embodiment to form a SiOC film on the second surface. When preparing the evaluation sample 4, adsorption sites on the first surface were regulated by the annealing treatment, and a modifying agent and a catalyst that satisfy b>a and c≤b−a were used. a, b, and c are as explained in the above-described embodiment. The process conditions in each step when preparing the evaluation sample 4 were the same as the process conditions in each step when preparing the evaluation sample 3 except for the process conditions (processing time) in the annealing treatment for adsorption site regulation. In the annealing treatment for adsorption site regulation, the processing temperature was set to 450 to 500 degrees C., and the processing time was set to be longer than the processing time when preparing the evaluation sample 3.

After preparing each evaluation sample, a difference between the thickness of the SiOC film formed on the second surface and the thickness of a SiOC film formed on the first surface in each evaluation sample (hereinafter referred to as a film thickness difference) was measured. That is, a difference obtained by subtracting the thickness of the SiOC film formed on the first surface from the thickness of the SiOC film formed on the second surface in each evaluation sample was measured.

As a result, the film thickness difference in the evaluation samples 1 and 2 was much larger than the film thickness difference in the evaluation samples 3 and 4, and it was confirmed that the evaluation samples 1 and 2 in Examples 1 and 2 provided much higher selectivity than the evaluation samples 3 and 4 in Comparative Examples 1 and 2.

According to the present disclosure in some embodiments, it is possible to selectively form a film on a desired surface with high precision.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, the method comprising:
forming an inhibitor layer on a first surface of a substrate having the first surface and a second surface by supplying a modifying agent to the substrate to adsorb inhibitor molecules contained in the modifying agent on the first surface; and
forming a film on the second surface by supplying a film-forming agent containing a catalyst to the substrate after forming the inhibitor layer on the first surface,
wherein a width of each of the inhibitor molecules is a, an interval between adsorption sites on the first surface is b, and a width of a catalyst molecule constituting the catalyst is c, and
wherein c>b−a is satisfied when a is smaller than b, and c>xb−a (x is the smallest integer that satisfies a<xb) is satisfied when a is larger than b.

2. The method of claim 1, wherein the act of forming the film includes supplying, as the catalyst, a catalyst having a molecular size that is hard to pass through an inter-molecular gap of the inhibitor molecules adsorbed on the first surface.

3. The method of claim 2, wherein the act of forming the film includes supplying, as the catalyst, a catalyst having a molecular size that is hard to pass through the inter-molecular gap to reach the first surface.

4. The method of claim 2, wherein the act of forming the film includes supplying, as the catalyst, a catalyst having a molecular size that is unable to pass through the inter-molecular gap.

5. The method of claim 2, wherein the act of forming the film includes supplying, as the catalyst, a catalyst having a molecular size larger than the inter-molecular gap.

6. The method of claim 1, further comprising: regulating the interval between the adsorption sites on the first surface before performing the act of forming the inhibitor layer.

7. The method of claim 1, further comprising: regulating a density of the adsorption sites on the first surface before performing the act of forming the inhibitor layer.

8. The method of claim 1, wherein the catalyst having a molecular size that satisfies c>b−a is used when a is smaller than b, and
wherein the catalyst having a molecular size that satisfies c>xb−a (x is the smallest integer that satisfies a<xb) is used when a is larger than b.

9. The method of claim 6, wherein in the act of regulating the interval between the adsorption sites on the first surface,
c>b−a is satisfied when b is larger than a, and
c>xb−a (x is the smallest integer that satisfies a<xb) is satisfied when b is smaller than a.

10. The method of claim 6, wherein in the act of regulating the interval between the adsorption sites on the first surface,
b is regulated so as to satisfy b>a and c>b−a, or
b is regulated so as to satisfy b<a and c>xb−a (x is the smallest integer that satisfies a<xb).

11. The method of claim 6, wherein
the adsorption sites on the first surface include an OH group.

12. The method of claim 1, wherein the catalyst is a basic catalyst.

13. The method of claim 1, wherein the inhibitor molecules contain an alkyl group.

14. The method of claim 1, wherein the inhibitor layer includes an alkyl group termination.

15. The method of claim 1, wherein the film-forming agent includes a raw material and a reactant.

16. The method of claim 15, wherein the act of forming the film includes alternately performing supplying the raw material to the substrate and supplying the reactant to the substrate, and supplying the catalyst to the substrate in at least one selected from the group of the act of supplying the raw material and the act of supplying the reactant.

17. The method of claim 1, wherein the first surface includes an oxygen-containing film, and the second surface includes a film made of a material different from a material of the oxygen-containing film.

18. A method of manufacturing a semiconductor device, comprising: the method of claim 1.

19. A substrate processing apparatus comprising:
a modifying agent supply system configured to supply a modifying agent to a substrate;
a film-forming agent supply system configured to supply a film-forming agent containing a catalyst to the substrate; and
a controller configured to be capable of controlling the modifying agent supply system and the film-forming agent supply system so as to perform a process including:
forming an inhibitor layer on a first surface of the substrate having the first surface and a second surface by supplying the modifying agent to the substrate to adsorb inhibitor molecules contained in the modifying agent on the first surface; and
forming a film on the second surface by supplying the film-forming agent containing the catalyst to the substrate after forming the inhibitor layer on the first surface,
wherein a width of each of the inhibitor molecules is a, an interval between adsorption sites on the first surface is b, and a width of a catalyst molecule constituting the catalyst is c, and
wherein c>b−a is satisfied when a is smaller than b, and c>xb−a (x is the smallest integer that satisfies a<xb) is satisfied when a is larger than b.

20. A non-transitory computer-readable recording medium storing a program that causes, by a computer, a substrate processing apparatus to perform a process including:
forming an inhibitor layer on a first surface of a substrate having the first surface and a second surface by supplying a modifying agent to the substrate to adsorb inhibitor molecules contained in the modifying agent on the first surface; and
forming a film on the second surface by supplying a film-forming agent containing a catalyst to the substrate after forming the inhibitor layer on the first surface,
wherein a width of each of the inhibitor molecules is a, an interval between adsorption sites on the first surface is b, and a width of a catalyst molecule constituting the catalyst is c, and
wherein c>b−a is satisfied when a is smaller than b, and c>xb−a (x is the smallest integer that satisfies a<xb) is satisfied when a is larger than b.
